(19) United States
(12) Patent Application Publication
(10) Pub. No.: US 2013/0208407 A1
(43) Pub. Date: Aug. 15, 2013

(54) BUILT-IN EARPHONE HOLDING STRUCTURE FOR ELECTRONIC DEVICES

(71) Applicants: SHENZHEN FUTAIHONG PRECISION INDUSTRY, (US); FIH (Hong Kong) Limited, (US)

(72) Inventors: YI-FENG HUANG, New Taipei (TW); XIAO-YAN CONG, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/671,521

(22) Filed: Nov. 7, 2012

(30) Foreign Application Priority Data
Feb. 13, 2012 (CN) 201210031110.5

(51) Int. Cl. B65H 75/34; H05K 5/02

(52) U.S. Cl. CPC B65H 75/34; H05K 5/02; H05K 5/0221
USPC 361/679.01; 242/389

(57) ABSTRACT

An earphone holding structure is for positioning an earphone including a cable and a head. The earphone holding structure includes a driving member, a first gear, a second gear, and a ratchet. The first gear is driven by the driving member to rotate. The second gear engages with the first gear, and the ratchet rotates along a single direction relative to the second gear. When the driving member drives the first gear to rotate, and rotates the second gear and the ratchet along a counterclockwise direction; when the ratchet is rotated along a clockwise direction, the second gear cannot rotate.

### BACKGROUND

1. Technical Field

The present disclosure relates to earphone holding structures, and more particularly, to a built-in earphone holding structure for an electronic device.

2. Description of Related Art

Portable electronic devices, such as tablet personal computer can use earphones to listen music. Since most electronic devices are not configured with an integrated earphone, the earphone needs to be separately prepared. Thus, the earphone may easily be lost. Additionally, the wire/cable of the earphone is easily knotted.

Therefore, there is room for improvement within the art.

### BRIEF DESCRIPTION OF THE DRAWINGS

Many aspects of the disclosed earphone holding structure can be better understood with reference to the following drawings. The components in the drawings are not necessarily drawn to scale, the emphasis instead being placed upon clearly illustrating the principles of the present earphone holding structure.

FIG. 1 is a schematic view of an electronic device with an earphone according to an exemplary embodiment.

FIG. 2 is an exploded view of a built-in earphone holding structure in the electronic device omitting the second housing.

FIG. 3 is a partially assembled view of the built-in earphone holding structure.

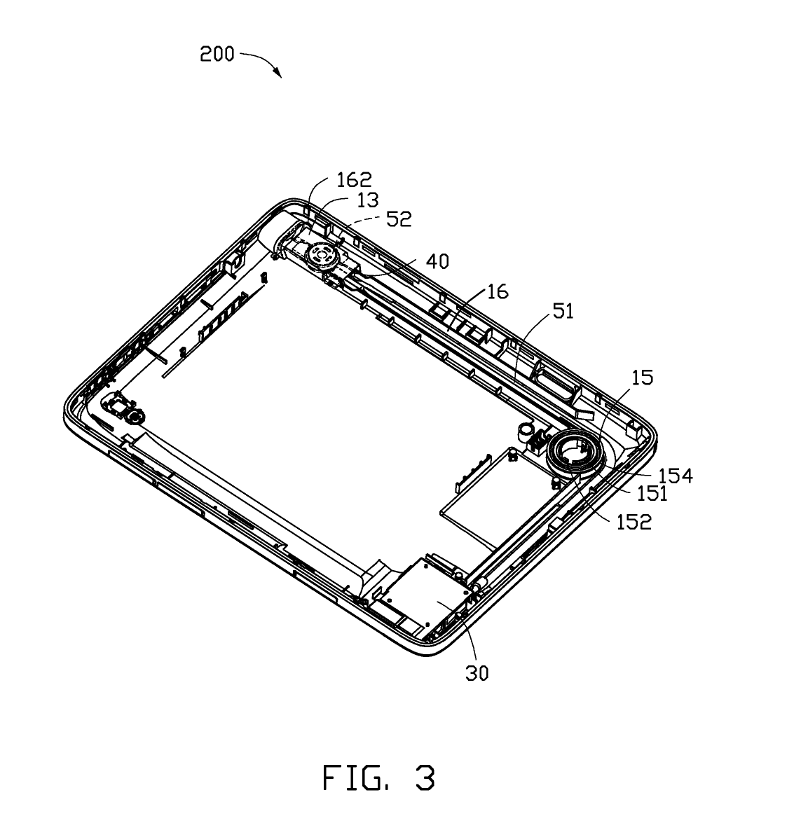

FIG. 4 is an exploded view of the containing module in FIG. 2.

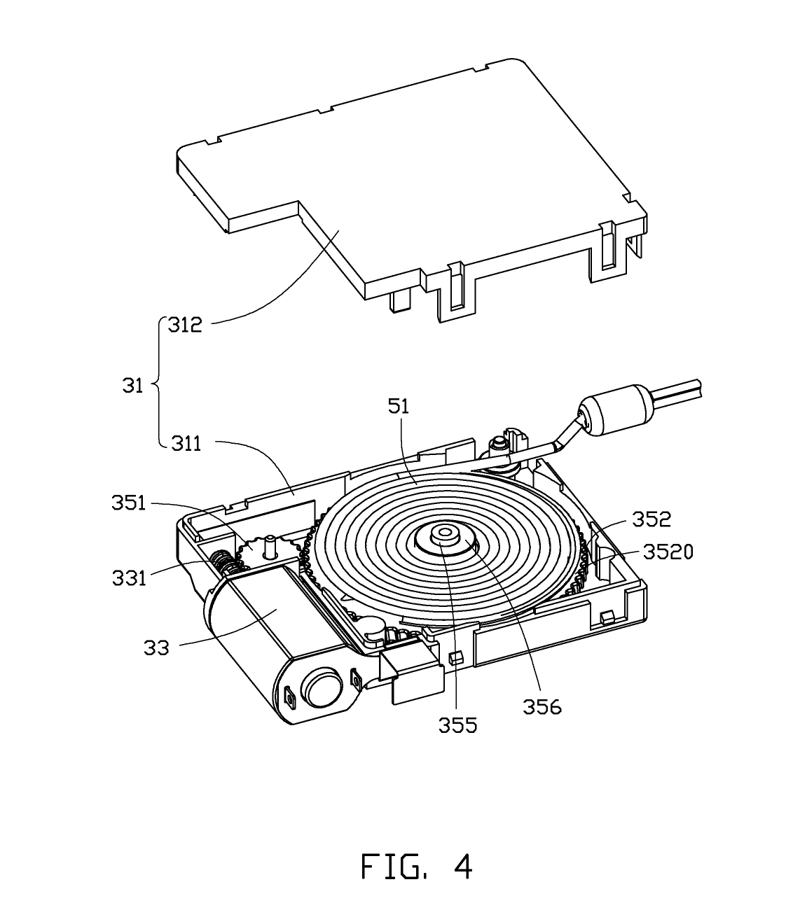

### DETAILED DESCRIPTION

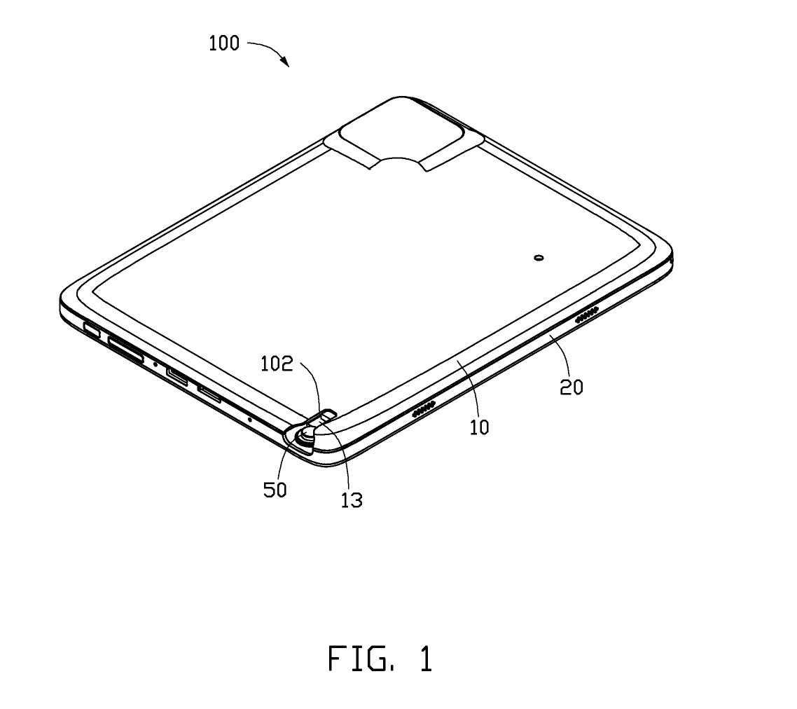

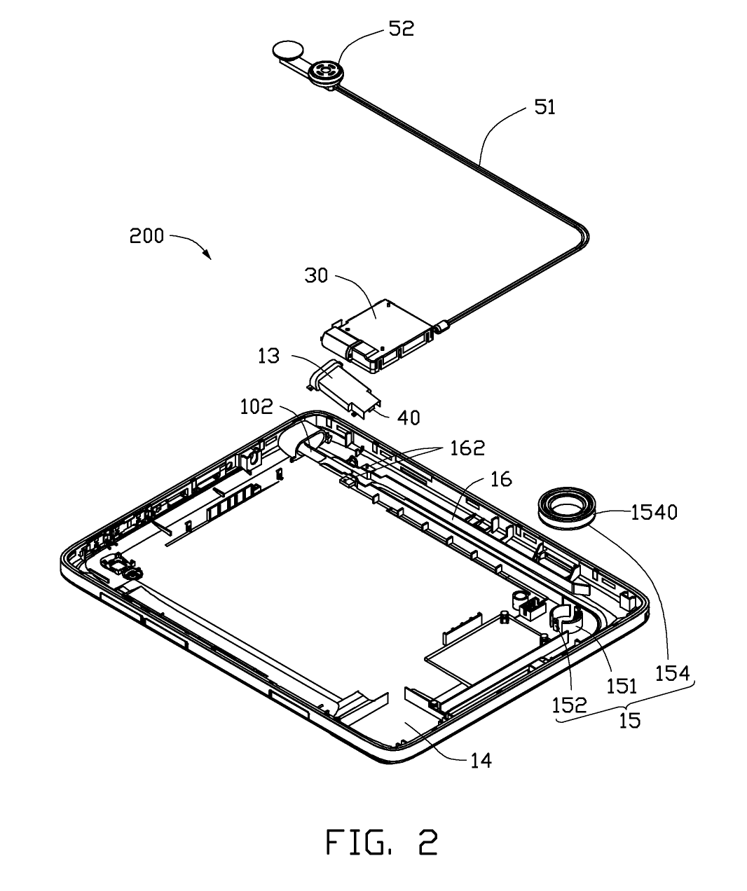

Referring to FIGS. 1 and 2, a portable electronic device 100 in accordance with an exemplary embodiment is shown. The portable electronic device 100 is a tablet personal computer including a first housing 10, a second housing 20, and an earphone holding structure 200. The second housing 20 is attached on the first housing 10. The earphone holding structure 200 is configured for receiving an earphone 50, and is positioned between the first housing 10 and the second housing 20. The earphone 50 includes a cable 51 and at least one earphone head 52. The earphone holding structure 200 includes a latching cover 13, a positioning portion 162, a receiving cavity 14, a guiding portion 15, a passage 16, a containing module 30 and a sensor 40. The sensor 40 is used for detecting the earphone head 52 in a predetermined position.

In the exemplary embodiment, the first housing 10 is a bottom housing of the electronic device. The first housing 10 defines an opening 102, at an outside surface thereof. The first housing 10 defines the receiving cavity 14 and the positioning portion 162 respectively defined at one diagonal line of the first housing 10. The receiving cavity 14 is configured for receiving the containing module 30. The positioning portion 162 is configured for mounting the latching cover 13 to allow the earphone head 52 to be received under the latching cover 13. The opening 102 allows the earphone head 52 to be mounted in the latching cover 13 to be exposed from the first housing 10. In the exemplary embodiment, the positioning portion 162 is made of a plurality of posts for mounting the latching cover 13. The guiding portion 15 is positioned at one end of another diagonal line of the first housing 10. The passage 16 is an L-shape passage defined along edges of the first housing 10 and connects the positioning portion 162 and the receiving cavity 14. When the earphone 50 is positioned on the first housing 10, the earphone head 52 is positioned under the latching cover 13; and the cable 51 is received in the passage 16 and partially coils around the guiding portion 15 and is connected to the containing module 30 in the receiving cavity 14.

The guiding portion 15 includes two arcuate sheets 151, two hooks 152, and a ring wheel 154. The arcuate sheets 151 are opposite to each other, and the hooks 152 are positioned between the two arcuate sheets 151. The ring wheel 154 is placed around and latched on the arucate sheets 151 and the hooks 152. An outer peripheral wall of the ring wheel 154 defines an annular groove 1540 for guiding the cable 51.

The containing module 30 includes a receiving box 31, a driving member 33, a first gear 351, a second gear 352, a shaft 355 and a ratchet 356. The receiving box 31 includes a main body 311 and a removable cover 312, detachably attached to the main body 311. The receiving box 31 is mounted to the receiving cavity 14. The driving member 33 is a motor and includes a screw 331. The second gear 352 and the ratchet 356 can rotate around the shaft 355. The ratchet 356 can rotate along a single direction relative to the second gear 352. When the driving member 33 rotates, the screw 331 drives the first gear 351 to rotate and further rotates the second gear 352 and the ratchet 356 along a counterclockwise direction. The second gear 352 includes a top surface 3520. One portion of the cable 51 can be coiled around the ratchet 356. When the coiled cable 51 is pulled out of the receiving box 31, the ratchet 356 rotates around the shaft 355 relative to the second gear 352 along a clockwise direction.

In use, the earphone head 52 is pulled out of the opening 102, and allows one portion of the cable 51 to move out of the receiving box 31. At the same time, the cable causes the ratchet 356 to rotate around the shaft 355 relative to the second gear 352 along the clockwise direction. When the cable 51 needs to be received in the electronic device 100, the driving member 33 is activated to rotate the screw 331. The second gear 352 is driven to automatically rotate and thus rotates the ratchet 356. Therefore, the cable 51 is automatically coiled around the ratchet 356. When the sensor 40 detects the earphone head 52 in the predetermined position, the sensor 40 will send a signal to the driving member 33 for stopping. The present earphone holding structure 200 is built-in between the first housing 10 and the second housing 20. The operation is easy and conveniently.

It is to be understood, however, that even through numerous characteristics and advantages of the present disclosure have been set forth in the foregoing description, together with details of assembly and function, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An earphone holding structure for positioning an earphone with a cable and a head, the earphone holding structure comprising:
a driving member;
a first gear engaging with the driving member;
a second gear engaging with the first gear; and
a ratchet rotating along a single direction relative to the second gear, and the ratchet is configured for coiling the cable;
wherein when the driving member drives the first gear to rotate, and the second gear and the ratchet are rotated along a counterclockwise direction; when the ratchet is rotated along a clockwise direction relative to the second gear, the second gear keeps stationary.

2. The earphone holding structure as claimed in claim 1, further comprising a receiving box, wherein the receiving box comprises a main body and a removable cover detachably attached to the main body.

3. The earphone holding structure as claimed in claim 2, further comprising a guiding portion, the guiding portion comprises two arcuate sheets, two hooks, and a ring wheel, the two arcuate sheets are opposite to each other, and the two hooks are positioned between the two arcuate sheets, and the ring wheel is placed around the two arcuate sheets and the two hooks.

4. An electronic device, comprising:
a housing defining a receiving cavity;
a receiving box received in the receiving cavity;
a driving member;
a first gear engaging with the driving member;
a second gear engaging with the first gear; and
a ratchet;
wherein when the driving member drives the first gear to rotate, and the second gear and the ratchet are rotated along a counterclockwise direction; when the ratchet is rotated along a clockwise direction relative to the second gear, the second gear cannot rotate.

5. The electronic device as claimed in claim 4, further comprising a latching cover, wherein the housing defines an opening at an outside surface thereof and a positioning portion at an inside surface thereof, and the latching cover is mounted on the positioning portion.

6. The electronic device as claimed in claim 5, wherein the receiving cavity and the positioning portion are respectively defined at one diagonal line of the first housing.

7. The electronic device as claimed in claim 6, further comprising a guiding portion, the guiding portion comprises two arcuate sheets, two hooks, and a ring wheel, the two arcuate sheets are opposite to each other, and the two hooks are positioned between the two arcuate sheets, and the ring wheel is placed around the two arucate sheets and the two hooks.

8. The electronic device as claimed in claim 6, wherein a passage is an L-shape passage defined along edges of the first housing, and connects the positioning portion and the receiving cavity.
